(19) United States
(12) Patent Application Publication
(10) Pub. No.: US 2024/0419627 A1
(43) Pub. Date: Dec. 19, 2024

(54) MULTI-CORE CHIP, INTEGRATED CIRCUIT APPARATUS, AND BOARD CARD AND MANUFACTURING PROCEDURE METHOD THEREFOR

(71) Applicant: Cambricon (Xi'an) Semiconductor Co., Ltd., Xi'an (CN)

(72) Inventors: Zhiwei QIU, Xi'an (CN); Shuai CHEN, Xi'an (CN); Song GAO, Xi'an (CN)

(21) Appl. No.: 18/698,629

(22) PCT Filed: Sep. 29, 2022
(86) PCT No.: PCT/CN2022/122372

§ 371 Date: Aug. 23, 2024

(30) Foreign Application Priority Data
Oct. 8, 2021 (CN) 202111172907.2

(51) Int. Cl. G06F 15/78

(52) U.S. Cl. CPC G06F 15/7814; G06F 15/7832

(57) ABSTRACT

The present disclosure relates to a multi-core chip, an integrated circuit device, a board card and a manufacturing method thereof, where the computing device of the present disclosure is included in an integrated circuit device, and the integrated circuit device includes a universal interconnection interface and other processing devices. The computing device interacts with other processing devices to jointly complete computing operations specified by the user. The integrated circuit device also includes a storage device, which is respectively connected to the computing device and other processing devices and is used for storing data of the computing device and other processing devices.

### CROSS REFERENCE OF RELATED APPLICATION

This application is a 371 of International Application No. PCT/CN2022/122372, filed Sep. 29, 2022, which claims the benefit and priority of Chinese Patent Application No. 202111172907.2 with the title of “MULTI-CORE CHIP, INTEGRATED CIRCUIT DEVICE, AND BOARD CARD AND MANUFACTURING PROCEDURE METHOD THEREFOR” filed on Oct. 8, 2021, the content of which is incorporated herein by reference in its entirety.

### TECHNICAL FIELD

The present disclosure generally relates to the field of semiconductor. Specifically, the present disclosure relates to a multi-core chip, an integrated circuit device, a board card, and a manufacturing procedure method therefor.

### BACKGROUND

Since the advent of the age of big data, system-level chips applying artificial intelligence technology are required to cope with increasingly complex environments, forcing system-level chips to develop more functions. At present, chip design has approached the maximum mask size. Therefore, developers try to divide a system-level chip into multi-chip modules, and the modules need to be connected at ultra-short and extra-short distances to achieve high speed data transfer between dies. In addition to expanding bandwidth as much as possible, die-to-die (D2D) connection is an extremely low-latency and extremely low-power solution.

A die-to-die interface is a functional block that occupies a small area of the die to provide a data interface between two modules or two dies assembled in a same package. Die-to-die interfaces use very short channels to connect modules or dies within a package, with transfer rate and bandwidth exceeding traditional chip-to-chip interfaces.

In the prior art, two modules or dies connected by die-to-die interfaces are usually placed side by side, and the die-to-die interfaces of the two modules or dies are adjacent. The two die-to-die interfaces are electrically connected through an interposer layer below. While the die-to-die interfaces deliver excellent transfer rates and bandwidth, the transfer path is as long as millimeters when transferring data through the underlying interposer layer. If a transfer path is too long, it will cause signal attenuation and speed reduction, and cannot meet the requirements for high-intensity computing.

Therefore, a technical solution that takes advantage of the die-to-die interface is urgently needed.

### SUMMARY

In order to at least partially solve the technical problems mentioned in the background art, the present disclosure provides a multi-core chip, an integrated circuit device, a board card, and a manufacturing procedure method therefor.

In a first aspect, the present disclosure relates to a multi-core chip including a first core layer and a second core layer. The first core layer includes a first operation area in which a first operation circuit is generated; and a first die-to-die area in which a first transceiver circuit is generated. The second core layer includes a second operation area in which a second operation circuit is generated; and a second die-to-die area in which a second transceiver circuit is generated. The first core layer and the second core layer are vertically stacked, and the first operation circuit and the second operation circuit transfer data between layers through the first transceiver circuit and the second transceiver circuit.

In a second aspect, the present disclosure relates to an integrated circuit device, including the aforementioned multi-core chip; and also relates to a board card including the aforementioned integrated circuit device.

In a third aspect, the present disclosure relates to a method for manufacturing a multi-core chip, including: generating a first core layer, where the first core layer includes a first operation area in which a first operation circuit is generated, and a first die-to-die area in which a first transceiver circuit is generated; and generating a second core layer, where the second core layer includes a second operation area in which a second operation circuit is generated, and a second die-to-die area in which a second transceiver circuit is generated. The first core layer and the second core layer are vertically stacked, and the first operation circuit and the second operation circuit transfer data between layers through the first transceiver circuit and the second transceiver circuit.

Through vertical stack in the die-to-die area, the multi-core chip of the present disclosure enables the two die to-die interfaces to transfer data without the interposer layer, so that the transfer path between the two die to die interfaces is greatly shortened, which helps to improve the transfer efficiency between cores.

### BRIEF DESCRIPTION OF THE DRAWINGS

By reading the following detailed description with reference to the accompanying drawings, the above-mentioned and other objects, features and technical effects of the exemplary embodiments of the present disclosure will become easier to understand. In the accompanying drawings, several embodiments of the present disclosure are shown in an exemplary but not restrictive manner, and the same or corresponding reference numerals indicate the same or corresponding parts of the embodiments. The drawings include the followings.

FIG. 1 shows a top view of layout of a package structure including a die-to-die interface;

FIG. 2 shows a cross-sectional view of the packaging structure of FIG. 1 along the dotted line direction;

FIG. 3 is a structural diagram of a board card in an embodiment of the present disclosure;

FIG. 4 is a diagram of a chip in an embodiment of the present disclosure;

FIG. 5 is a structural diagram of an integrated circuit device operation device in a first embodiment of the present disclosure;

FIG. 6 is a diagram of vertical stack in a second embodiment of the present disclosure;

FIG. 7 is a diagram of vertical stack in a third embodiment of the present disclosure;

FIG. 8 is a diagram of vertical stack in a fourth embodiment of the present disclosure;

FIG. 9 is a diagram of vertical stack in a fifth embodiment of the present disclosure;

FIG. 10 is a diagram of vertical stack in a sixth embodiment of the present disclosure;

FIG. 11 is a flow chart for manufacturing the multi-core chip of FIG. 4 in a seventh embodiment of the present disclosure;

FIG. 12 is a flow chart for manufacturing the multi-core chip of FIG. 6 in a eighth embodiment of the present disclosure;

FIG. 13 is a flow chart for manufacturing the multi-core chip of FIG. 7 in a ninth embodiment of the present disclosure;

FIG. 14 is a flow chart for manufacturing the multi-core chip of FIG. 8 in a tenth embodiment of the present disclosure;

FIG. 15 is a flow chart for manufacturing the multi-core chip of FIG. 9 in a eleventh embodiment of the present disclosure; and

FIG. 16 is a flow chart for manufacturing the multi-core chip of FIG. 10 in a twelfth embodiment of the present disclosure.

### DETAILED DESCRIPTION OF THE EXAMPLES

Technical solutions in embodiments of the present disclosure will be described clearly and completely hereinafter with reference to the accompanied drawings in the embodiments of the present disclosure. Obviously, the embodiments to be described are merely some rather than all embodiments of the present disclosure. All other examples obtained by those skilled in the art based on the examples of the present disclosure without creative efforts shall fall within the protection scope of the present disclosure.

It should be understood that terms such as “first”, “second”, “third”, and “fourth” in the claims, the specification, and drawings are used for distinguishing different objects rather than describing a specific order. It should be understood that the terms “including” and “comprising” used in the specification and the claims indicate the presence of a feature, an entity, a step, an operation, an element, and/or a component, but do not exclude the existence or addition of one or more other features, entities, steps, operations, elements, components, and/or collections thereof.

It should also be understood that the terms used in the specification of the present disclosure are merely intended to describe specific embodiments rather than to limit the present disclosure. As being used in the specification and the claims of the disclosure, unless the context clearly indicates otherwise, the singular forms “a”, “an” and “the” are intended to include the plural forms. It should also be understood that the term “and/or” used in the specification and the claims refers to any and all possible combinations of one or more of relevant listed items and includes these combinations.

As being used in this specification and the claims, the term “if” can be interpreted as “when”, or “once” or “in response to a determination” or “in response to a case where something is detected” depending on the context.

The embodiments of the present disclosure will be described in detail below with reference to the drawings.

A die-to-die interface is just like any other chip-to-chip interface, establishing a data link channel between two dies. The die-to-die interface is logically divided into a physical layer, a link layer, and a transaction layer, and provides a standardized parallel interface to connect to the internal interconnect structure.

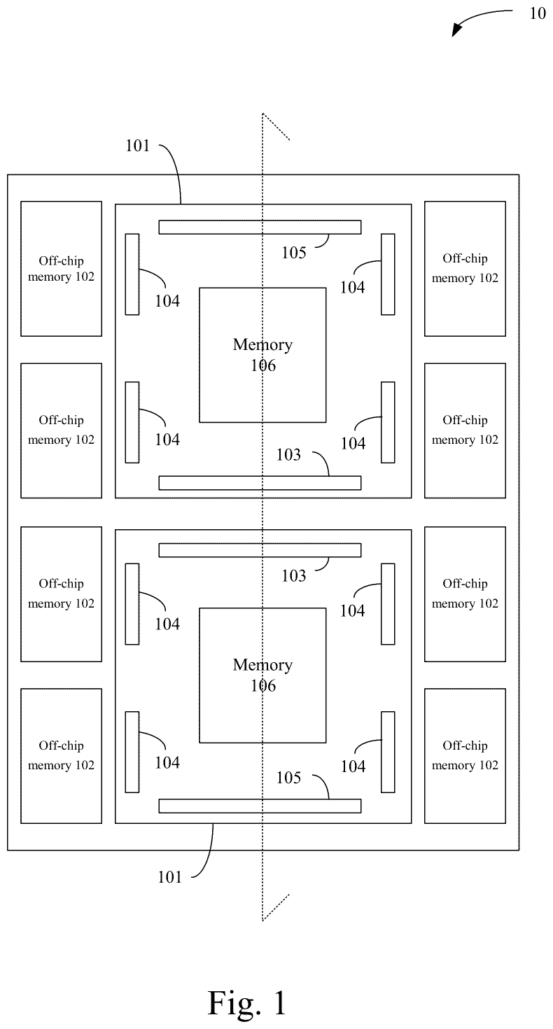

FIG. 1 shows a top view of layout of a package structure including a die-to-die interface. The layout of this package structure is located in a molding compound area 10 of the chip. The molding compound area 10 includes system areas and storage areas. This exemplary system areas are located in the center of the molding compound area 10 to place two on-chip systems 101. The storage areas are located on both sides of the system areas and are used to place 8 off-chip memories 102.

The system areas are also provided with die-to-die areas 103, physical areas 104, and input/output areas 105. The die-to-die areas 103 are generated with transceiver circuits for data sharing between two on-chip systems 101. The physical areas 104 are generated with physical access circuits for accessing the off-chip memories 102. The input/output areas 105 are generated with input/output circuits which are used as interfaces for the on-chip systems 101 to communicate with the outside.

Memories 106 are also placed in the system areas as temporary storage space for the on-chip systems 101. The capacity of the memories 106 is smaller than that of the off-chip memories 102, but the data transfer rate of the memories 106 is higher than that of the off-chip memories 102.

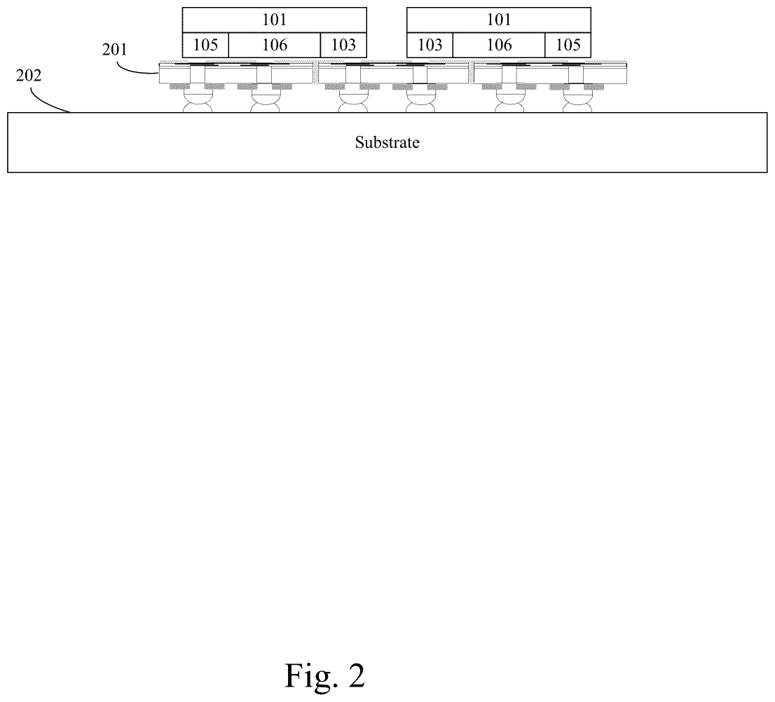

FIG. 2 shows a cross-sectional view of the packaging structure of FIG. 1 along the dotted line direction. As shown in the figure, the system areas include two layers: an upper layer includes the on-chip systems 101, and a lower layer includes the transceiver circuits of the die-to-die areas 103, the memories 106, and the input/output circuits of the input/output areas 105. The packaging structure also includes an interposer layer 201 and a substrate 202. The interposer layer 201 is disposed on the substrate 202. When two on-chip systems 101 perform data transfer, the path is: the on-chip systems 101 at a sending end→the transceiver circuits of the die-to-die areas 103 at the sending end→the interposer layer 201→the transceiver circuits of the die-to-die areas 103 at a receiving end→the on-chip systems 101 at the receiving end, so as to achieve the technical efficacy of low latency and low power consumption of die-to-die ports.

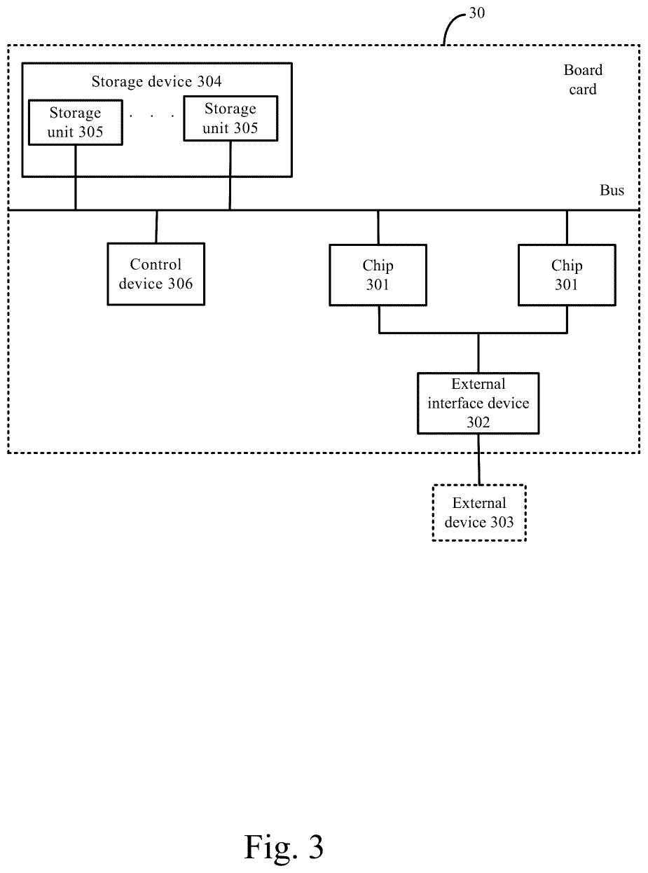

FIG. 3 is a structural diagram of a board card 30 in an embodiment of the present disclosure. As shown in FIG. 3, the board card 30 includes chips 301, each of which is a system-level chip integrated with one or more combined processing devices. The combined processing device is an artificial intelligence computing unit for supporting various types of deep learning and machine learning algorithms to meet the intelligent processing needs in complex scenarios in fields such as computer vision, speech, natural language processing, and data mining. In particular, deep learning technology is widely used in the field of cloud intelligence. A significant feature of cloud intelligence applications is the large amount of input data, which has high requirements on the storage and computing capabilities of the platform. The board card 30 of this embodiment is suitable for cloud intelligent applications and has huge off-chip storage, on-chip storage and powerful computing capabilities.

The chips 301 are connected to an external device 303 through an external interface device 302. The external device 303 may be a server, a computer, a camera, a monitor, a mouse, a keyboard, a network card, a WIFI interface, and the like. Data to be processed can be transferred to the chips 301 from the external device 303 through the external interface device 302. Operation results of the chips 301 can be transferred back to the external device 303 via the external interface device 302. According to different application scenarios, the external interface device 302 may have different interface forms, such as PCIe interface.

In more detail, the chips 301 may include a computing device and a processing device. The computing device is configured to perform user-specified operations, and is mainly implemented as a single-core intelligent processor or a multi-core intelligent processor to perform deep learning or machine learning calculations. The processing device, as a general processing device, performs basic control including but not limited to data transfer, starting and/or stopping the computing device, and the like. Depending on the implementation, the processing device may be one or more types of processors such as a central processing unit (CPU), a graphics processing unit (GPU), or other general-purpose and/or special-purpose processor. These processors include, but are not limited to, a digital signal processor (DSP), an application specific integrated circuit (ASIC), a field-programmable gate array (FPGA) or other programmed logic device, a discrete gate or transistor logic device, a discrete hardware component, etc. Their number can be determined according to actual needs. As mentioned above, only for the computing device of this embodiment, it can be regarded as having a single-core structure or a homogeneous multi-core structure. However, when the computing device and the processing device are integrated and considered together, they are considered to form a heterogeneous multi-core structure.

The board card 30 also includes a storage device 304 for storing data, which includes one or more storage units 305. A storage device 304 connects and transfers data with a control device 306 and the chips 301 through a bus. The control device 306 in the board card 30 is configured to control the status of the chips 301. To this end, in one application scenario, the control device 306 may include a micro controller unit (MCU).

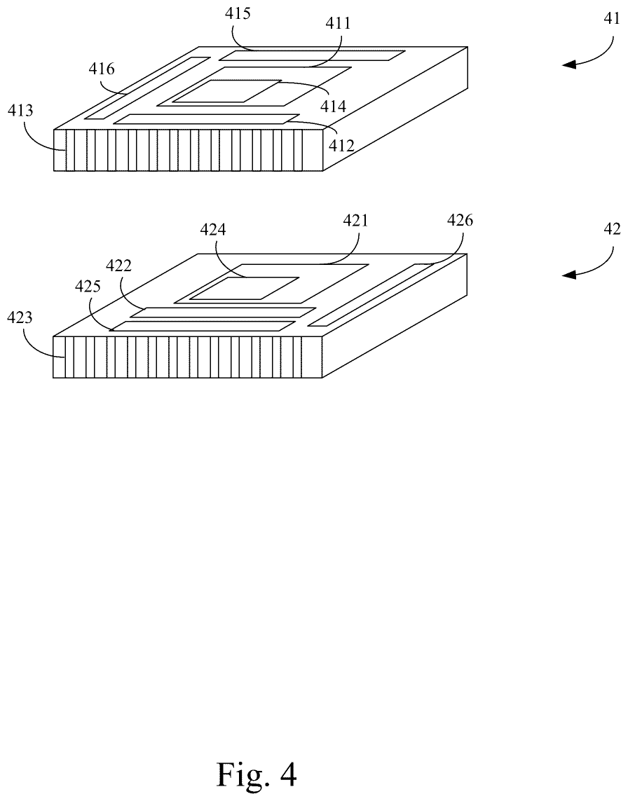

FIG. 4 shows a schematic diagram of the chip 301 of this embodiment. The chip 301 is a multi-core chip including a first core layer 41 and a second core layer 42. In fact, the first core layer 41 and the second core layer 42 are vertically stacked together. The first core layer 41 and the second core layer 42 in FIG. 4 are visually separated up and down for the convenience of explanation.

The first core layer 41 includes a first operation area 411, a first die-to-die area 412 and first through silicon vias (TSV) 413. The first operation area 411 is generated with a first operation circuit to realize functions of the computing device. The first die-to-die area 412 is generated with a first transceiver circuit to serve as a die-to-die interface for the first operation circuit. The first TSVs 413 are used to realize electrical interconnection of stacked chips in a three-dimensional integrated circuit. The second core layer 42 includes a second operation area 422, a second die-to-die area 422 and second through silicon vias (TSV) 423. The second operation area 421 is generated with a second operation circuit to realize functions of the processing device. The second die-to-die area 422 is generated with a second transceiver circuit to serve as a die-to-die interface for the second operation circuit. The second TSVs 423 are used to realize electrical interconnection of stacked chips in a three-dimensional integrated circuit.

In this embodiment, the first operation area 411 is generated with a memory area 414 for temporarily storing operation results of the first operation circuit, and the second operation area 421 is also generated with a memory area 424 for temporarily storing operation results of the second operation circuit. The memory area 414 and the memory area 424 are directly arranged in the first operation area 411 and the second operation area 421 respectively. Data may be transferred without an interposer layer, so the data transfer rate is high.

The first core layer 41 also includes an input/output area 415 and a physical area 416, and the second core layer 42 also includes an input/output area 425 and a physical area 426. The input/output area 415 is generated with an input/output circuit, which serves as an interface for the first core layer 41 to communicate with the outside. The input/output area 425 is also generated with an input/output circuit, which is used as an interface for the second core layer 42 to communicate with the outside. The physical area 416 is generated with a physical access circuit, which is used as an interface for the first core layer 41 to access the off-chip memories. The physical area 426 is generated with a physical access circuit, which is used as an interface for the second core layer 42 to access the off-chip memories.

When the computing device and the processing device are to exchange data, and the first operation circuit and the second operation circuit transfer data between layers through the first transceiver circuit and the second transceiver circuit. Specifically, when the computing device is to transfer data to the processing device, the data reaches the processing device through the following path: the first operation circuit in the first computing area 411→the first transceiver circuit of the first die-to-die area 412→the first TSVs 413→the second transceiver circuit in the second die-to-die area 422→the second operation circuit of the second operation area 421. When the processing device is to transfer data to the computing device, the data reaches the processing device through the following path: the second operation circuit of the second operation area 421→the second transceiver circuit of the second die-to-die area 422→the first TSVs 413→the first transceiver circuit of the first die-to-die area 412→the first operation circuit of the first computing area 411.

When operation results of the computing device are required to exchange with data of other off-chip devices, the memory area 414 transfers the data to other devices through input/output circuits. Specifically, when the data in the memory area 414 is to be transferred to other off-chip devices, the data reaches other off-chip devices through the following paths: the input/output circuit of the input/output area 415→the first TSVs 413→the second TSVs 423; when other off-chip devices are to transfer data to the memory area 414, the data reaches the memory area 414 through a reverse path of a reverse path of the aforementioned path. It should be noted that some specific TSVs among the first TSVs 413 and the second TSVs 423 are specially designed to electrically conduct data of the input/output circuit.

When the operation results of the processing device are required to exchange with data of other off-chip devices, the data in the memory area 424 reaches other off-chip devices through the following path: the input/output circuit of the input/output area 425→the second TSVs 423; when other off-chip devices are to transfer data to the memory area 424, the data reaches the memory area 424 through a reverse path of the aforementioned path.

When the operation results of the computing device need to be stored in the off-chip memories through the physical area 416, the memory area 414 transfers the data to the off-chip memories through the physical access circuit. Specifically, when the data in the memory area 414 is to be transferred to the off-chip memories, the data reaches the off-chip memories through the following path: the physical access circuit of the physical area 416→the first TSVs 413→the second TSVs 423; when the off-chip memories are to transfer input data to the memory area 414 for processing by the computing device, the data reaches the memory area 414 through a reverse path of the aforementioned path. It should be noted that some specific TSVs among the first TSVs 413 and the second TSVs 423 are specially designed to electrically conduct data of the physical access circuit.

When the operation results of the processing device need to be stored in the off-chip memories through the physical area 426, the memory area 424 transfers the data to the off-chip memories through the physical access circuit. Specifically, when the data in the memory area 424 is to be transferred to the off-chip memories, the data reaches the off-chip memories through the following path: the physical access circuit of the physical area 426→the second TSVs 423; when the off-chip memories are to transfer input data to the memory area 424 for processing by the computing device, the data reaches the memory area 424 through a reverse path of the aforementioned path.

As shown in FIG. 4, the first die-to-die area 412 and the second die-to-die area 422 are vertically stacked, such that the die-to-die interface of the first core layer 41 is electrically connected to the die-to-die interface of the second core layer 42 directly through the first TSVs 413 without using the interposer layer 201 as shown in FIG. 2 for transfer. The length of the TSVs is about ten micrometers. Compared with the millimeter-level length of the interposer layer, data transfer in this embodiment is faster and the signal strength is better.

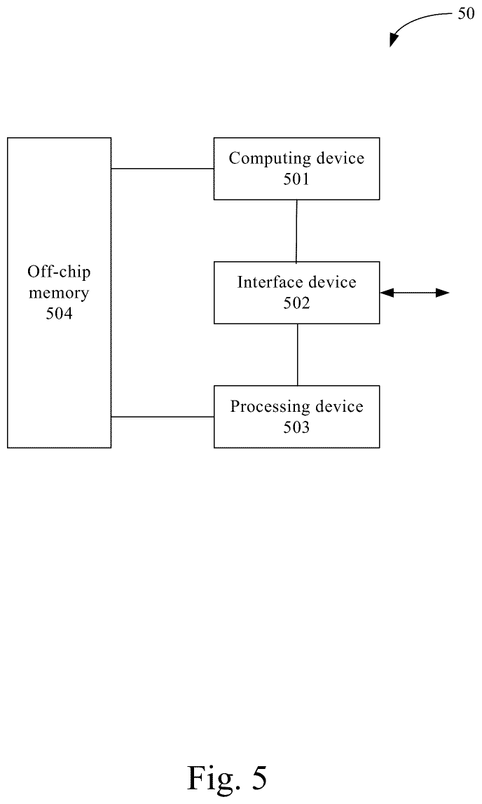

Another embodiment of the present disclosure also provides the board card 30 shown in FIG. 3, and the structure of the combined processing device in the chip 301 is shown in FIG. 5. The combined processing device 50 includes a computing device 501, an interface device 502, a processing device 503 and an off-chip memory 504.

The computing device 501 is configured to perform user-specified operations, and is mainly implemented as a single-core intelligent processor or a multi-core intelligent processor to perform deep learning or machine learning calculations. The computing device 501 can interact with the processing device 503 through the interface device 502 to complete user-specified operations together.

The interface device 502 is connected to the bus to connect with other devices, such as the control device 306 in FIG. 3, the external interface device 302, etc.

The processing device 503, as a general processing device, performs basic control including but not limited to data transfer, starting and/or stopping the computing device, and the like. Depending on the implementation, the processing device 503 may be one or more types of processors such as a CPU, a GPU, or other general-purpose and/or special-purpose processor. These processors include, but are not limited to, a DSP, an ASIC, an FPGA or other programmed logic device, a discrete gate or transistor logic device, a discrete hardware component, etc. Their number can be determined according to actual needs. As mentioned above, only for the computing device 501 of this embodiment, it can be regarded as having a single-core structure or a homogeneous multi-core structure. However, when the computing device 501 and the processing device 503 are integrated and considered together, they are considered to form a heterogeneous multi-core structure.

The off-chip memory 504 is used to store data to be processed. It is a DDR memory, usually 16G or larger in size, and is used to save data of the computing device 501 and/or the processing device 503.

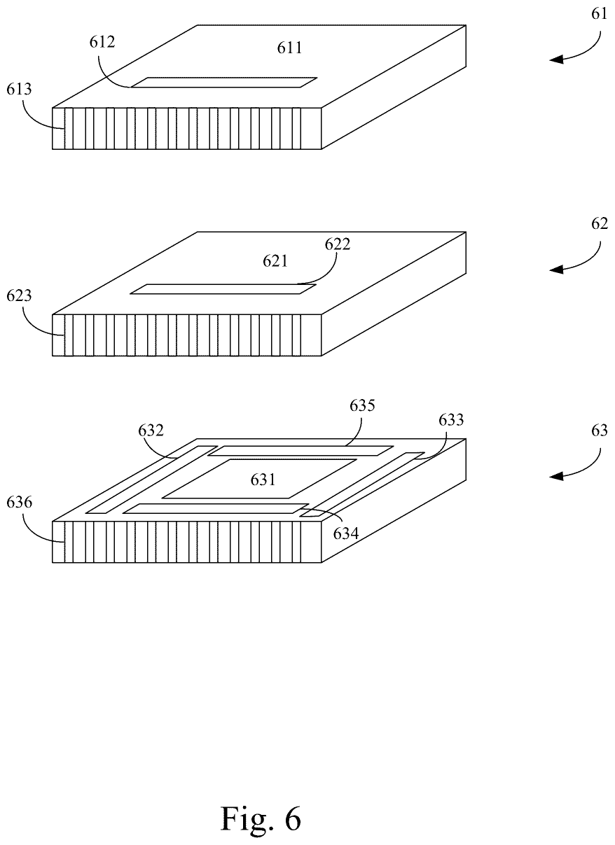

FIG. 6 is a diagram of vertical stack in this embodiment. This embodiment also shows a multi-core chip, including a first core layer 61, a second core layer 62 and a memory layer 63. In fact, the first core layer 61, the second core layer 62 and the memory layer 63 are vertically stacked together in sequence from top to bottom. Each layer in FIG. 6 is visually separated from top to bottom and is shown in this manner for convenience of illustration only.

The first core layer 61 includes a first operation area 611. The first operation area 611 covers the logic layer of the first core layer 61, which is the top side of the first core layer 61 in the figure. The first core layer 61 also includes the first die-to-die area 612 and first TSVs 613 in a special area. The second core layer 62 includes a second operation area 621. The second operation area 621 covers the logic layer of the second core layer 62, which is the top side of the second core layer 62 in the figure. The second core layer 62 also includes the second die-to-die area 622 and second TSVs 623 in a special area. The first die-to-die area 612 and the second die-to-die area 622 are positioned vertically opposite to each other. The function and effect of the multi-core chip are the same as those of the previous embodiments, so they will not be described again.

The memory layer 63 includes a memory area 631, a first input/output area 632, a second input/output area 633, a first physical area 634, a second physical area 635 and third TSVs 636. The memory area 631 is generated with a storage unit for temporarily storing operation results of the first operation circuit or the second operation circuit. The first input/output area 632 is generated with a first input/output circuit, which is used as an interface for the first operation circuit to communicate with the outside, to realize the function of the interface device 502. The second input/output area 633 is generated with a second input/output circuit, which is used as an interface for the second computing circuit to communicate with the outside, and also realizes the function of the interface device 502. The first physical area 634 is generated with a first physical access circuit for sending operation results of the first operation circuit stored in the memory area 631 to the off-chip memory 504. The second physical area 635 is generated with a second physical access circuit for sending operation results of the second operation circuit stored in the memory area 631 to the off-chip memory 504. The third TSVs 636 extend throughout the entire memory area 62, and are only shown on one side in the example, for electrically connecting specific components.

When the computing device 501 and the processing device 503 need to exchange data, the first operation circuit and the second operation circuit transfer data between layers through the first transceiver circuit and the second transceiver circuit. Specifically, when the computing device 501 is to transfer data to the processing device 503, the data reaches the processing device 503 through the following path: the first operation circuit of the first operation area 611→the first transceiver circuit in the first die-to-die area 612→the first TSVs 613→the second transceiver circuit in the second die-to-die area 622→the second operation circuit in the second operation area 621. When the processing device 503 is to transfer data to the computing device 501, the data reaches the computing device 501 through a reverse path of the aforementioned path. It should be noted that some specific TSVs among the first TSVs 613 are specially designed to electrically connect the first transceiver circuit and the second transceiver circuit.

When the operation results of the computing device 501 are required to exchange with data of other off-chip devices through the interface device 502, the memory area 631 transfers the data to other devices through the first input/output circuit. Specifically, when the data in the memory area 631 is to be transferred to other off-chip devices, the data reaches other off-chip devices through the following paths: the input/output circuit of the input/output area 632→the third TSVs 636; when other off-chip devices are to exchange data with the computation device 501, the data reaches the memory area 631 through a reverse path of the aforementioned path.

When the operation results of the processing device 503 are required to exchange with data of other off-chip devices through the interface device 502, the memory area 631 transfers the data to other devices through the second input/output circuit. Specifically, when the data in the memory area 631 is to be transferred to other off-chip devices, the data reaches other off-chip devices through the following paths: the input/output circuit of the second input/output area 633→the third TSVs 636; when other off-chip devices are to exchange data with the processing device 503, the data reaches the memory area 631 through a reverse path of the aforementioned path.

It should be noted that some specific TSVs in the third TSVs 636 are specially designed to electrically conduct data of the first and second input/output circuits.

When the operation results of the computing device 501 need to be stored in the off-chip memory 504 through the first physical area 634, the memory area 631 transfers the data to the off-chip memory 504 through the first physical access circuit. Specifically, when the data in the memory area 631 is to be transferred to the off-chip memory 504, the data reaches the off-chip memory 504 through the following path: the first physical access circuit of the first physical area 634→the third TSVs 636; when the off-chip memory 504 is to transfer input data to the memory area 631 for processing by the computing device 501, the data reaches the memory area 631 through a reverse path of the aforementioned path.

When the operation results of the processing device 503 need to be stored in the off-chip memory 504 through the second physical area 635, the memory area 631 transfers the data to the off-chip memory 504 through the second physical access circuit. Specifically, when the data in the memory area 631 is to be transferred to the off-chip memory 504, the data reaches the off-chip memory 504 through the following path: the second physical access circuit of the second physical area 635→the third TSVs 636; when the off-chip memory 504 are to transfer input data to the memory area 631 for processing by the processing device 503, the data reaches the memory area 631 through a reverse path of the aforementioned path.

It should be noted that some specific TSVs in the third TSVs 636 are specially designed to electrically conduct the first physical access circuit and data of the first physical access circuit.

As shown in FIG. 6, the first die-to-die area 612 and the second die-to-die area 622 are vertically stacked, such that the die-to-die interface of the first core layer 61 is electrically connected to the die-to-die interface of the second core layer 62 directly through the first TSVs 613 without using the interposer layer 201 as shown in FIG. 2 for transfer.

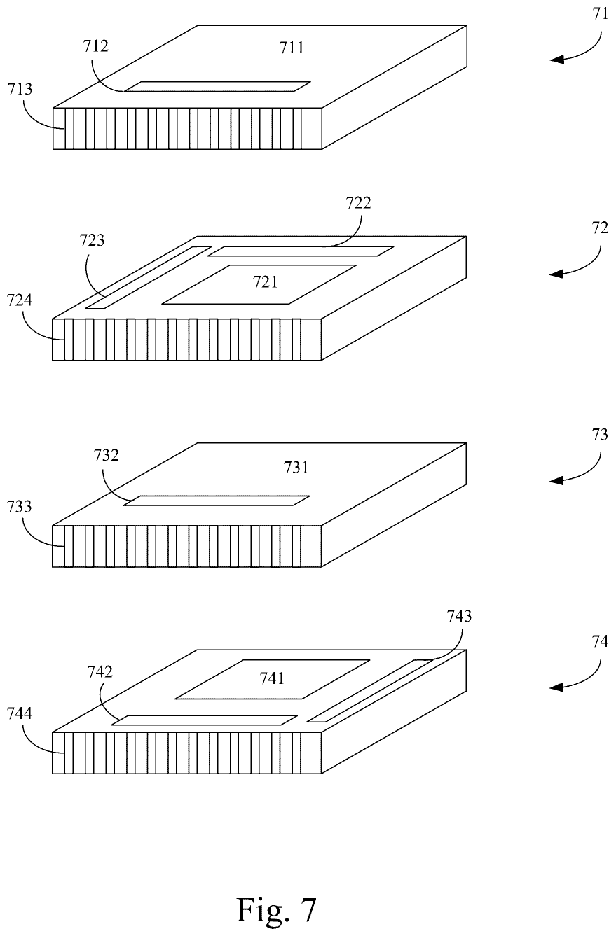

Another embodiment of the present invention also implements the structure shown in FIG. 5. FIG. 7 is a diagram of vertical stack in this embodiment. This embodiment also shows a multi-core chip, including a first core layer 71, a first memory layer 72, a second core layer 73 and a second memory layer 74. In fact, the first core layer 71, the first memory layer 72, the second core layer 73 and the second memory layer 74 are vertically stacked vertically in sequence. Each layer in FIG. 7 is visually separated from top to bottom and is shown in this manner for convenience of illustration only.

The first core layer 71 includes a first operation area 711. The first operation area 711 covers a logic layer of the first core layer 71, which is the top side of the first core layer 71 in the figure. The first core layer 71 also includes a first die-to-die area 712 and a first TSVs 713 in a special area. The second core layer 73 includes a second operation area 731. The second operation area 731 covers a logic layer of the second core layer 73, which is the top side of the second core layer 73 in the figure. The second core layer 73 also includes a second die-to-die area 732 and a second TSVs 733 in a special area. Its functions and effects are the same as those of the above-mentioned embodiment, so they will not be described in detail.

The first memory layer 72 includes a first memory area 721, a first input/output area 722, a first physical area 723 and third TSVs 724. The first memory area 721 is generated with a storage unit for temporarily storing operation results of the first operation circuit. The first input/output area 722 generates a first input/output circuit, which is used as an interface for the first core layer 71 and the first memory layer 72 to communicate with the outside, that is, to realize the function of the interface device 502. The second physical area 723 is generated with a first physical access circuit for accessing the off-chip memory 504. The third TSVs 724 extend throughout the entire first memory area 72, and are only shown on one side in the example, for electrically connecting specific components.

The second memory layer 74 includes a second memory area 741, a second input/output area 742, a second physical area 743 and fourth TSVs 744. The second memory area 741 is generated with a storage unit for temporarily storing operation results of the second operation circuit. The second input/output area 742 generates a second input/output circuit, which is used as an interface for the second core layer 73 and the second memory layer 74 to communicate with the outside, that is, to realize the function of the interface device 502. The second physical area 743 is generated with a second physical access circuit for accessing the off-chip memory 504. The fourth TSVs 744 extend throughout the entire second memory area 74, and are only shown on one side in the example, for electrically connecting specific components.

The TSVs of each layer, if necessary, will include transceiver TSVs, input/output TSVs, and physical TSVs. The transceiver TSVs are used to electrically connect the first transceiver circuit and the second transceiver circuit. The input/output TSVs are used to electrically conduct data of the input/output circuits. The physical TSVs are used to electrically conduct operation results of the operation circuits to the off-chip memory 504.

When the computing device 501 is to transfer data to the processing device 503, the data reaches the processing device 503 through the following path: the first operation circuit of the first operation area 711→the first transceiver circuit in the first die-to-die area 712→a transceiver TSV of the first TSVs 713→a transceiver TSV of the third TSVs 724→the second transceiver circuit in the second die-to-die area 732→the second operation circuit in the second operation area 731. When the processing device 503 is to transfer data to the computing device 501, the data reaches the computing device 501 through a reverse path of the aforementioned path.

When the operation results of the computing device 501 are required to exchange with data of other off-chip devices through the interface device 502, the data reaches other off-chip devices through the following path: the first input/output circuit of the first input/output area 722→an input/output TSV of the third TSVs 724→an input/output TSV of the second TSVs 733→an input/output TSV of the fourth TSVs 744; when other off-chip devices are to transfer data to the first memory area 721, the data reaches the first memory area 721 through a reverse path of the aforementioned path. When the operation results of the processing device 503 are required to exchange with data of other off-chip devices through the interface device 502, the data reaches other off-chip devices through the following path: the input/output circuit of the second input/output area 742→the input/output TSV of the fourth TSVs 744; when other off-chip devices are to transfer data to the second memory area 741, the data reaches the second memory area 741 through a reverse path of the aforementioned path.

When the data in the first memory area 721 is to be transferred to the off-chip memory 504, the data reaches the off-chip memory 504 through the following path: a first physical access circuit of the first physical area 723→a physical TSV of the third TSVs 724→a physical TSV of the second TSVs 733→a physical TSV of the fourth TSVs 744; when the off-chip memory 504 is to transfer input data to the first memory area 721 for processing by the computing device 501, the data reaches the first memory area 721 through a reverse path of the aforementioned path. When the data in the second memory area 741 is to be transferred to the off-chip memory 504, the data reaches the off-chip memory 504 through the following path: a second physical access circuit of the second physical area 743→the physical TSV of the fourth TSVs 744; when the off-chip memory 504 are to transfer input data to the second memory area 741 for processing by the processing device 503, the data reaches the second memory area 741 through a reverse path of the aforementioned path.

In this embodiment, the first core layer 71 is used in combination with the first memory layer 72, and the second core layer 73 is used in combination with the second memory layer 74. For improving transfer efficiency, the first core layer 71 and the first memory layer 72 are manufactured by face-to-face bonding, so that the transfer path between the first operation circuit and the first memory area 721 is the shortest. The second core layer 73 and the second memory layer 74 are manufactured by face-to-face bonding, so that the transfer path between the second operation circuit and the second memory area 741 is also the shortest. To achieve the aforementioned shortest transfer path, the first memory layer 72 and the second core layer 73 are manufactured by back-to-back bonding.

As shown in FIG. 7, the first die-to-die area 712 and the second die-to-die area 732 are vertically stacked, such that the die-to-die interface of the first core layer 71 is electrically connected to the die-to-die interface of the second core layer 73 directly through the first TSVs 713 and the third TSVs 724 without using the interposer layer 201 as shown in FIG. 2 for transfer.

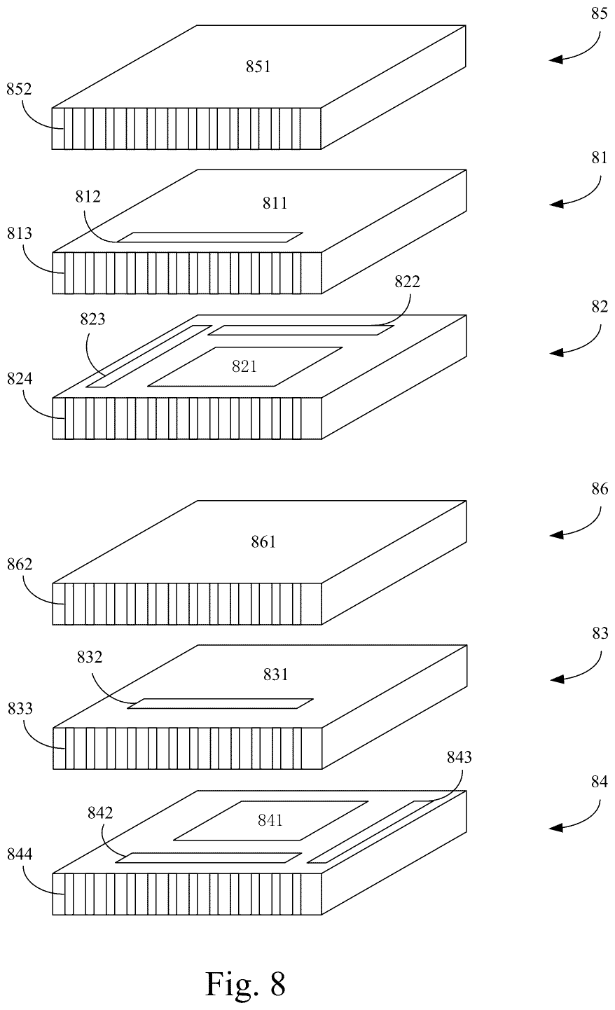

Another embodiment of the present invention also implements the structure shown in FIG. 5. FIG. 8 is a diagram of vertical stack in this embodiment. The multi-core chip of this embodiment includes a first core layer 81, a first memory layer 82, a second core layer 83, a second memory layer 84, a third memory layer 85 and a fourth memory layer 86. In more detail, the multi-core chip of this embodiment is divided into a first die group and a second die group. The first die group is stacked on the second die group. The first die group includes respectively the third memory layer 85, the first core layer 81 and the first memory layer 82 from top to bottom. The second die group includes respectively the fourth memory layer 86, the second core layer 83 and the second memory layer 84 from top to bottom, which means the fourth memory layer 86 is located between the first memory layer 82 and the second core layer 83. The layers in FIG. 8 are visually separated into upper and lower parts only for the convenience of explanation.

The functions and effects of the first core layer 81, the first memory layer 82, the second core layer 83, and the second memory layer 84 are the same as those of the first core layer 71, the first memory layer 72, the second core layer 73, and the second memory layer 74 in the aforementioned embodiment, so they are not repeated here.

The third memory layer 85 includes a third memory area 851 and fifth TSVs 852, The third memory area 851 covers an entire logic layer of the third memory layer 85, i.e., the top side of the third memory layer 85 in the figure. The third memory area 851 is generated with a storage unit for temporarily storing operation results of the first operation circuit. The fifth TSVs 852 extend throughout the entire third memory area 85, and are only shown on one side in the example, for electrically connecting specific components. The third memory layer 85 is only responsible for temporarily storing the operation results of the first operation circuit, and is not responsible for external communication tasks of the first die group. The first operation circuit may use temporary storage space of the first memory area 821 and the third memory area 851. When the computing device 501 is to temporarily store intermediate data, it may temporarily store the intermediate data in the third memory area 851 through the fifth TSVs 852, or temporarily store the intermediate data in the first memory area 821 through the first TSVs 813.

The fourth memory layer 86 includes a fourth memory area 861 and sixth TSVs 862. The fourth memory area 861 covers an entire logic layer of the fourth memory layer 86, i.e., the top side of the fourth memory layer 86 in the figure. The fourth memory area 861 is generated with a storage unit for temporarily storing operation results of the second operation circuit. The sixth TSVs 862 extend throughout the entire fourth memory area 86, and are only shown on one side in the example, for electrically connecting specific components. The fourth memory layer 86 is only responsible for temporarily storing the operation results of the second operation circuit, and is not responsible for external communication tasks of the second die group. The second operation circuit may use temporary storage space of the second memory area 841 and the fourth memory area 861. When the computing device 503 is to temporarily store intermediate data, it may temporarily store the intermediate data in the fourth memory area 861 through the sixth TSVs 862, or temporarily store the intermediate data in the second memory area 841 through the second TSVs 833.

The TSVs of each layer, if necessary, will include transceiver TSVs, input/output TSVs, and physical TSVs. The transceiver TSVs are used to electrically connect the first transceiver circuit and the second transceiver circuit. The input/output TSVs are used to electrically conduct data of the input/output circuits. The physical TSVs are used to electrically conduct operation results of the operation circuits to the off-chip memory 504.

When the computing device 501 is to transfer data to the processing device 503, the data reaches the processing device 503 through the following path: the first operation circuit of the first operation area 811→the first transceiver circuit in the first die-to-die area 812→a transceiver TSV of the first TSVs 813→a transceiver TSV of the third TSVs 824→a transceiver TSV of the sixth TSVs 862→the second transceiver circuit in the second die-to-die area 832→the second operation circuit in the second operation area 831. When the processing device 503 is to transfer data to the computing device 501, the data reaches the computing device 501 through a reverse path of the aforementioned path.

When the operation results of the first die group are required to exchange with data of other off-chip devices through the interface device 502, the data reaches other off-chip devices through the following path: the first input/output circuit of the first input/output area 822→an input/output TSV of the third TSVs 824→an input/output TSV of the sixth TSVs 862→an input/output TSV of the second TSVs 833→an input/output TSV of the fourth TSVs 844; when other off-chip devices are to transfer data to the first die group, the data reaches the first memory area 821 through a reverse path of the aforementioned path. When the operation results of the second die group are required to exchange with data of other off-chip devices through the interface device 502, the data reaches other off-chip devices through the following path: a second input/output circuit of the second input/output area 842→the input/output TSV of the fourth TSVs 844; when other off-chip devices are to transfer data to the second die group, the data reaches the second memory area 841 through a reverse path of the aforementioned path.

When the data in the first die group is to be transferred to the off-chip memory 504, the data reaches the off-chip memory 504 through the following path: a first physical access circuit of the first physical area 823→a physical TSV of the third TSVs 824→a physical TSV of the sixth TSVs 862→a physical TSV of the second TSVs 833→a physical TSV of the fourth TSVs 844; when the off-chip memory 504 is to transfer input data to the first die group for processing by the computing device 501, the data reaches the first memory area 821 through a reverse path of the aforementioned path. When the data in the second die group is to be transferred to the off-chip memory 504, the data reaches the off-chip memory 504 through the following path: the second physical access circuit of the second physical area 843→the physical TSV of the fourth TSVs 844; when the off-chip memory 504 are to transfer input data to the second die group for processing by the processing device 503, the data reaches the second memory area 841 through a reverse path of the aforementioned path.

In this embodiment, the first core layer 81 is used in combination with the first memory layer 82 and the third memory layer 85, and the second core layer 83 is used in combination with the second memory layer 84 and the fourth memory layer 86. For improving transfer efficiency, the first core layer 81 and the first memory layer 82 are manufactured by face-to-face bonding, so that the transfer path between the first operation circuit and the first memory area 821 is the shortest. The first core layer 81 and the third memory layer 85 are manufactured by face-to-back bonding, the first memory layer 82 and the fourth memory layer 86 are manufactured by back-to-back bonding, and the second core layer 83 and the fourth memory layer 86 are manufactured by face-to-face bonding, so that the transfer path between the second operation circuit and the fourth memory area 861 is also the shortest. The second core layer 83 and the second memory layer 84 are manufactured by face-to-back bonding.

As shown in FIG. 8, the first die-to-die area 812 and the second die-to-die area 832 are vertically stacked, such that the die-to-die interface of the first core layer 81 is electrically connected to the die-to-die interface of the second core layer 83 directly through the first TSVs 813, the third TSVs 824 and the sixth TSVs 862 without using the interposer layer 201 as shown in FIG. 2 for transfer.

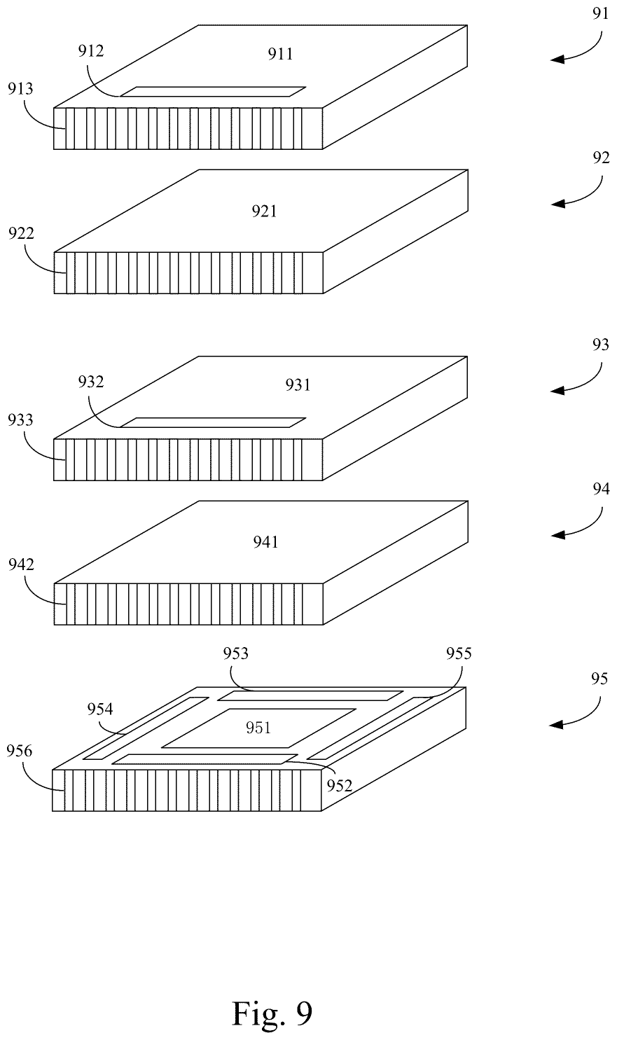

Another embodiment of the present invention also implements the structure shown in FIG. 5. FIG. 9 is a diagram of vertical stack in this embodiment. The multi-core chip of this embodiment is divided into a first die group, a second die group and a third die group which are stacked from top to bottom. The first die group includes a first core layer 91 and a first memory layer 92 from top to bottom, the second die group includes a second core layer 93 and a second memory layer 94 from top to bottom, and the third die group includes only a third memory layer 95, so the third memory layer 95 is located below the second memory layer 94. The layers in FIG. 9 are visually separated into upper and lower parts only for the convenience of explanation.

The first core layer 91 includes a first operation area 911. The first operation area 911 covers a logic layer of the first core layer 91, which is the top side of the first core layer 91 in the figure. The first core layer 91 also includes a first die-to-die area 912 and a first TSVs 913 in a special area. The first memory layer 92 includes a first memory area 921 and a second TSVs 922. The first memory area 921 covers a logic layer of the first memory layer 92, which is the top side of the first memory layer 92 in the figure. The first memory area 921 is generated with a storage unit for temporarily storing operation results of the first operation circuit. The second core layer 93 includes a second operation area 931. The second operation area 931 covers a logic layer of the second core layer 93, which is the top side of the second core layer 93 in the figure. The second core layer 93 also includes a second die-to-die area 932 and third TSVs 933 in a special area. The second memory layer 94 includes a second memory area 941 and fourth TSVs 942. The second memory area 941 covers a logic layer of the second memory layer 94, which is the top side of the second memory layer 94 in the figure. The second memory area 941 is generated with a storage unit for temporarily storing operation results of the second operation circuit.

The third memory layer 95 includes a third memory area 951, a first input/output area 952, a second input/output area 953, a first access physical area 954, a second physical access area 955 and fifth TSVs 956. The third memory area 951 is generated with a storage unit for temporarily storing operation results of the first operation circuit or the second operation circuit. The first input/output area 952 is generated with a first input/output circuit, which is used as an interface for the first die group to communicate with the outside, to realize the function of the interface device 502. The second input/output area 953 is generated with a second input/output circuit, which is used as an interface for the second die group to communicate with the outside, and also realizes the function of the interface device 502. The first access physical area 954 is generated with a first physical access circuit for communicating the first die group and the off-chip memory 504. The second access physical area 955 is generated with a second physical access circuit for communicating the second die group and the off-chip memory 504.

The TSVs extend throughout the entire layer, and are only shown on one side in the example. The TSVs of each layer, if necessary, will include transceiver TSVs, input/output TSVs, and physical TSVs, respectively. The transceiver TSVs are used to electrically connect the first transceiver circuit and the second transceiver circuit. The input/output TSVs are used to electrically conduct data of the input/output circuits. The physical TSVs are used to electrically conduct operation results of the operation circuits to the off-chip memory 504.

When the computing device 501 is to transfer data to the processing device 503, the data reaches the processing device 503 through the following path: the first operation circuit of the first operation area 911→the first transceiver circuit in the first die-to-die area 912→a transceiver TSV of the first TSVs 913→a transceiver TSV of the second TSVs 922→the second transceiver circuit in the second die-to-die area 932→the second operation circuit in the second operation area 931. When the processing device 503 is to transfer data to the computing device 501, the data reaches the computing device 501 through a reverse path of the aforementioned path.

The first die group and the second die group do not directly communicate to the outside of the chip. When the communication to the outside of the chip is required, this embodiment is implemented through the third memory layer 95 of the third die group.

When the operation results of the computing device 501 are required to exchange with data of other off-chip devices through the interface device 502, the data may be transferred to the third memory area 951 through the input/output TSVs of each layer for temporary storage, and then reach other off-chip devices via the third memory area 951 through the following path: a first input/output circuit of the second input/output area 952→a first input/output TSV of the fifth TSVs 956; when other off-chip devices are to transfer data to the first die group, the data is first temporarily stored in the third memory area 951 through a reverse path of the aforementioned path, and then transferred from the third memory area 951 to the first memory area 921.

When the operation results of the processing device 503 are required to exchange with data of other off-chip devices through the interface device 502, the data may be transferred to the third memory area 951 through the input/output TSVs of each layer for temporary storage, and then reach other off-chip devices via the third memory area 951 through the following path: a second input/output circuit of the second input/output area 953→a second input/output TSV of the fifth TSVs 956; when other off-chip devices are to transfer data to the second die group, the data is first temporarily stored in the third memory area 951 through a reverse path of the aforementioned path, and then transferred from the third memory area 951 to the second memory area 941.

When the data in the first memory area 921 is to be transferred to the off-chip memory 504, the data may be transferred to the third memory area 951 through the input/output TSVs of each layer for temporary storage, and then reach other off-chip devices via the third memory area 951 through the following path: a first physical access circuit of the first access physical area 954→a first physical TSV of the fifth TSVs 956; when the off-chip memory 504 are to transfer input data to the first die group, the input data is first temporarily stored in the third memory area 951 through a reverse path of the aforementioned path, and then transferred from the third memory area 951 to the first memory area 921.

When the data in the second memory area 941 is to be transferred to the off-chip memory 504, the data may be transferred to the third memory area 951 through a physical TSV of the fourth TSVs for temporary storage, and then reach other off-chip devices via the third memory area 951 through the following path: a second physical access circuit of the second access physical area 955→a second physical TSV of the fifth TSVs 956; when the off-chip memory 504 are to transfer input data to the second die group, the input data is first temporarily stored in the third memory area 951 through a reverse path of the aforementioned path, and then transferred from the third memory area 951 to the second memory area 941 through the physical TSV of the fourth TSVs.

In this embodiment, the first core layer 91 is used in combination with the first memory layer 92, and the second core layer 93 is used in combination with the second memory layer 94. For improving transfer efficiency, the first core layer 91 and the first memory layer 92 are manufactured by face-to-face bonding, so that the transfer path between the first operation circuit and the first memory area 921 is the shortest. The second core layer 93 and the second memory layer 94 are manufactured by face-to-face bonding, so that the transfer path between the second operation circuit and the second memory area 941 is also the shortest. To achieve the aforementioned shortest transfer path, the first memory layer 92 and the second core layer 93 are manufactured by back-to-back bonding, and the second memory layer 94 and the third core layer 95 are manufactured by face-to-back bonding.

As shown in FIG. 9, the first die-to-die area 912 and the second die-to-die area 932 are vertically stacked, such that the die-to-die interface of the first core layer 91 is electrically connected to the die-to-die interface of the second core layer 93 directly through the first TSVs 913 and the second TSVs 922 without using the interposer layer 201 as shown in FIG. 2 for transfer.

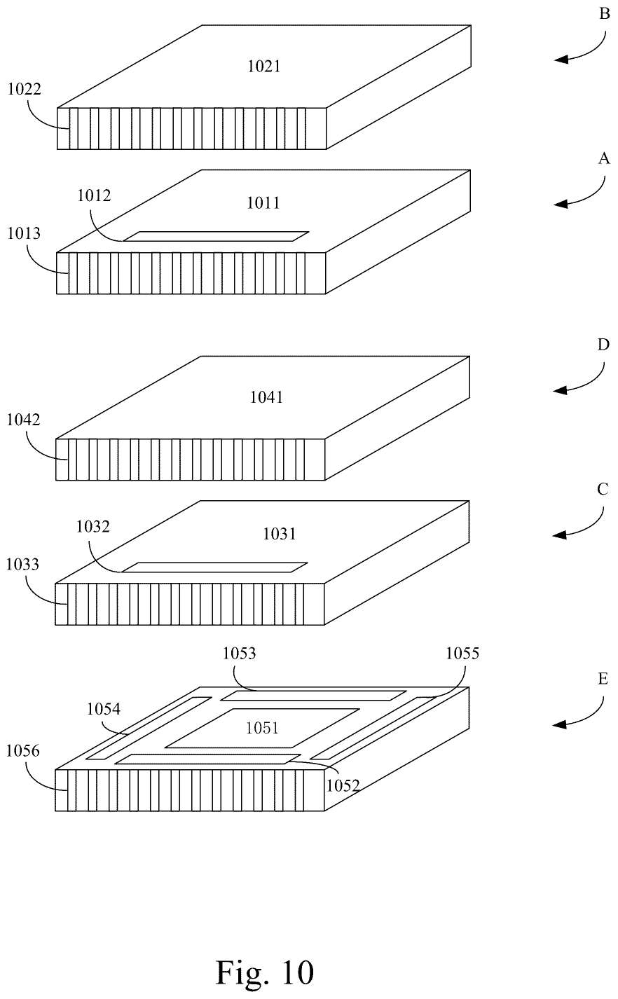

Another embodiment of the present invention also implements the structure shown in FIG. 5. FIG. 10 is a diagram of vertical stack in this embodiment. The multi-core chip of this embodiment is divided into a first die group, a second die group and a third die group which are stacked from top to bottom. The first die group includes a third memory layer B and a first core layer A from top to bottom, the second die group includes a first memory layer D and a second core layer C from top to bottom, and the third die group includes only a second memory layer E. Obviously, the only difference between the vertical stacking structure of this embodiment and the embodiment of FIG. 9 is that positions of the core layer and the memory layer of the first die group and the second die group are swapped. Based on the description of the aforementioned embodiments, those skilled in the art can know the coordination method between the layers of this embodiment without creative work, so it is not repeated here.

The above-mentioned embodiments are all a vertically stacked system-on-chip, which may be implemented by using FCBGA (flip chip ball grid array) or CoWoS (chip on wafer on substrate) packaging process. FCBGA is a packaging format known as flip chip ball grid array. FCBGA uses small balls instead of pins to connect circuits and may provide the shortest distance of external connections. The use of this packaging can provide excellent electrical performance, reduce the loss and inductance between component interconnections, reduce electromagnetic interference, and withstand higher frequencies. CoWoS is an integrated production technology. Dies are first connected to the silicon wafer through the CoW packaging process, and then the CoW dies are connected to the substrate, integrating into CoWoS. Through this technology, multiple dies may be packaged together, achieving the technical effects of small package size, low power consumption and few pins.

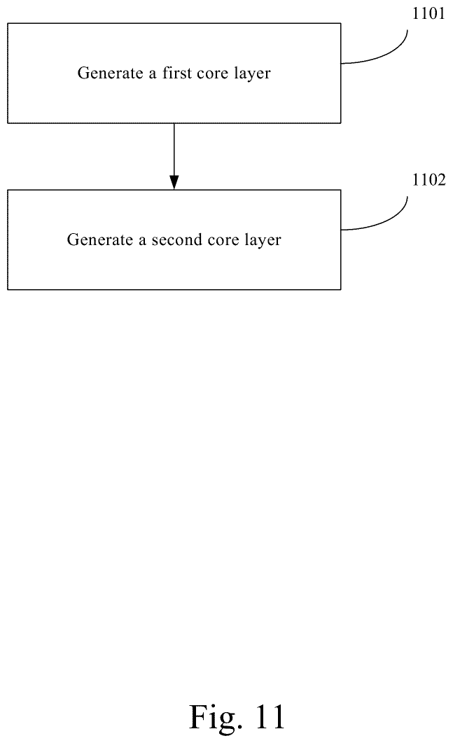

Another embodiment of the present disclosure provides a method for manufacturing a multi-core chip as shown in FIG. 4, and a flow chart thereof is shown in FIG. 11.

In step 1101, a first core layer 41 is generated, including a first operation area 411 and a first die-to-die area 412. The first operation area 411 is generated with a first operation circuit; and a first die-to-die area 412 is generated with a first transceiver circuit. In this step, a transceiver TSV is generated in the first core layer 41 to electrically connect the first transceiver circuit and a second transceiver circuit.

In step 1102, a second core layer 42 is generated, including a second operation area 421 and a second die-to-die area 422. The second operation area 421 is generated with a second operation circuit; and a second die-to-die area 422 is generated with the second transceiver circuit.

The first core layer 41 and the second core layer 42 are vertically stacked, and the first operation circuit and the second operation circuit transfer data between layers through the first transceiver circuit and the second transceiver circuit. Those skilled in the art can understand the technical means of this embodiment through the description of the embodiment of FIG. 4, so it is not described in detail.

In this embodiment, the first die-to-die area 412 and the second die-to-die area 422 are vertically stacked, such that the die-to-die interface of the first core layer 41 is electrically connected to the die-to-die interface of the second core layer 42 directly through the first TSVs 413 without using the interposer layer 201 as shown in FIG. 2 for transfer.

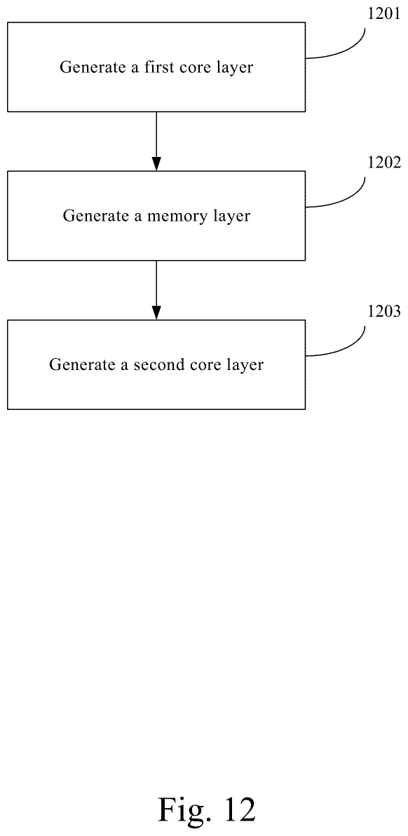

Another embodiment of the present disclosure provides a method for manufacturing a multi-core chip as shown in FIG. 6, and a flow chart thereof is shown in FIG. 12.

In step 1201, a first core layer 61 is generated, including a first operation area 611 and a first die-to-die area 612. The first operation area 611 is generated with a first operation circuit; and a first die-to-die area 612 is generated with a first transceiver circuit. In this step, a transceiver TSV is generated in the first core layer 61 to electrically connect the first transceiver circuit and a second transceiver circuit.

In step 1202, a memory layer 63 is generated, in which a memory area 631, an input/output area 632, a first physical area 634 and TSVs 624 are generated. The memory area 631 is generated with a storage unit for temporarily storing the operation results of the first operation circuit and a second operation circuit. The input/output area 632 is generated with an input/output circuit to serve as an interface for the multi-core chip to communicate with the outside. The first physical area 634 is generated with a physical access circuit to access the off-chip memory 504. The TSV 624 is configured to electrically connect the first transceiver circuit and the second transceiver circuit. In this step, a transceiver TSV is generated in the memory layer 63 to electrically connect the first transceiver circuit and the second transceiver circuit. Specifically, a portion of the TSVs 624 are configured as transceiver TSVs.

In step 1203, a second core layer 62 is generated, including a second operation area 621 and a second die-to-die area 622. The second operation area 621 is generated with the second operation circuit; and a second die-to-die area 622 is generated with the second transceiver circuit.

In this embodiment, the first core layer 61, the memory layer 63 and the second core layer 62 are stacked in sequence, which means the memory layer 63 is generated between the first core layer 61 and the second core layer 62. The first die-to-die area 612 and the second die-to-die area 622 are vertically stacked, such that a die-to-die interface of the first core layer 61 is electrically connected to a die-to-die interface of the second core layer 62 directly through a first TSVs 613 and third TSVs 636 without using the interposer layer 201 as shown in FIG. 2 for transfer.

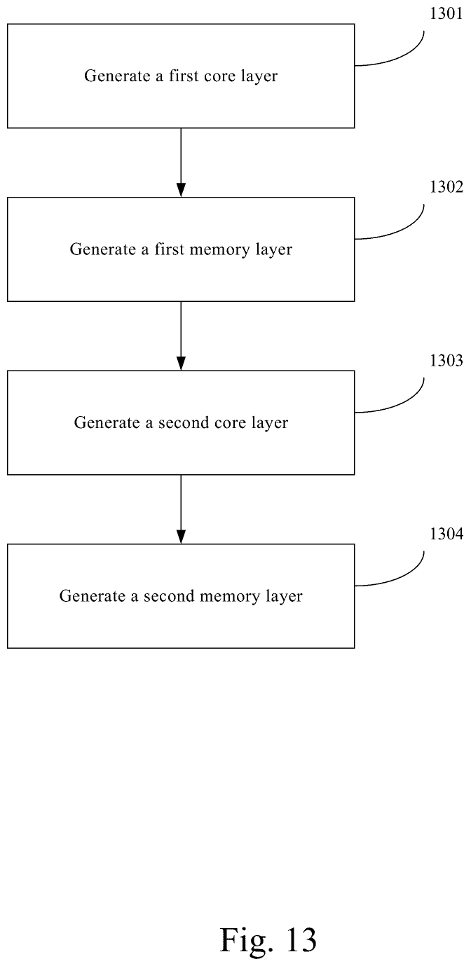

Another embodiment of the present disclosure provides a method for manufacturing a multi-core chip as shown in FIG. 7, and a flow chart thereof is shown in FIG. 13.

In step 1301, a first core layer 71 is generated, including a first operation area 711 and a first die-to-die area 712. The first operation area 711 is generated with a first operation circuit; and the first die-to-die area 712 is generated with a first transceiver circuit. In this step, a transceiver TSV is generated in the first core layer 71 to electrically connect the first transceiver circuit and a second transceiver circuit.

In step 1302, a first memory layer 72 is generated, including a first memory area 721 generated with a storage unit for temporarily storing operation results of the first operation circuit. In this step, a transceiver TSV is generated in the first memory layer 72 to electrically connect the first transceiver circuit and the second transceiver circuit.

In step 1303, a second core layer 73 is generated, including a second operation area 731 and a second die-to-die area 732. The second operation area 731 is generated with a second operation circuit; and a second die-to-die area 732 is generated with the second transceiver circuit.

In step 1304, a second memory layer 74 is generated, including a second memory area 741 generated with a storage unit for temporarily storing operation results of the second operation circuit. In this step, a transceiver TSV is generated in the second memory layer 74 to electrically connect the first transceiver circuit and the second transceiver circuit.

In this embodiment, the first core layer 71, the first memory layer 72, the second core layer 73, and the second memory layer 74 are stacked in sequence. More specifically, the first die-to-die area 712 and the second die-to-die area 732 are vertically stacked, such that a die-to-die interface of the first core layer 71 is electrically connected to a die-to-die interface of the second core layer 73 directly through the transceiver TSV without using the interposer layer 201 as shown in FIG. 2 for transfer.

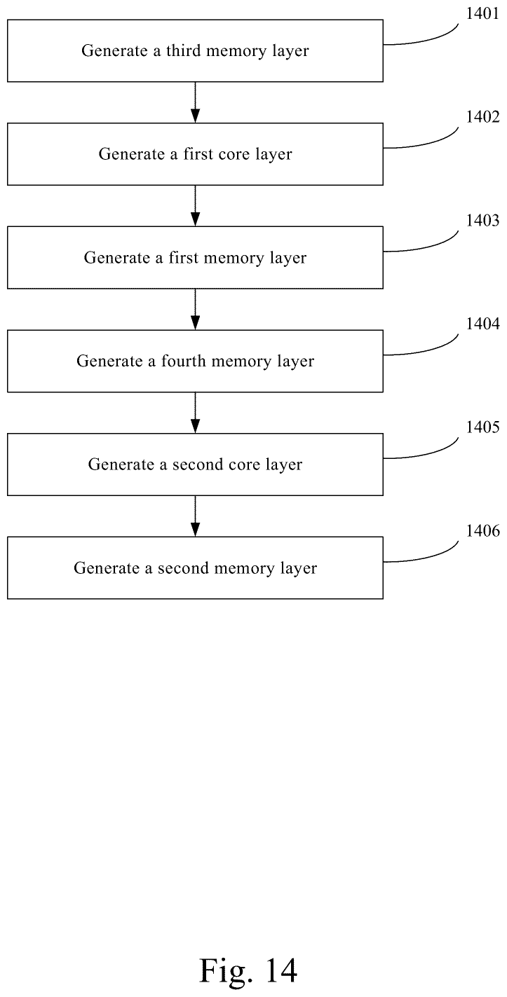

Another embodiment of the present disclosure provides a method for manufacturing a multi-core chip as shown in FIG. 8, and a flow chart thereof is shown in FIG. 14.

In step 1401, a third memory layer 85 is generated, including a third memory area 851 generated with a storage unit for temporarily storing operation results of a first operation circuit.

In step 1402, a first core layer 81 is generated, including a first operation area 811 and a first die-to-die area 812. The first operation area 811 is generated with the first operation circuit; and the first die-to-die area 812 is generated with a first transceiver circuit. In this step, a transceiver TSV is generated in the first core layer 81 to electrically connect the first transceiver circuit and a second transceiver circuit.

In step 1403, a first memory layer 82 is generated, including a first memory area 821 generated with a storage unit for temporarily storing operation results of the first operation circuit. In this step, a transceiver TSV is generated in the first memory layer 82 to electrically connect the first transceiver circuit and the second transceiver circuit.

In step 1404, a fourth memory layer 86 is generated, including a fourth memory area 861 generated with a storage unit for temporarily storing operation results of the second operation circuit. The fourth memory layer 86 is located between the first memory layer 82 and the second core layer 83. In this step, a transceiver TSV is generated in the fourth memory layer 86 to electrically connect the first transceiver circuit and the second transceiver circuit.

In step 1405, a second core layer 83 is generated, including a second operation area 831 and a second die-to-die area 832. The second operation area 831 is generated with a second operation circuit; and a second die-to-die area 832 is generated with the second transceiver circuit.

In step 1406, a second memory layer 84 is generated, including a second memory area 841 generated with a storage unit for temporarily storing operation results of the second operation circuit. In this step, a transceiver TSV is generated in the second memory layer 84 to electrically connect the first transceiver circuit and the second transceiver circuit.

In this embodiment, the third memory layer 85, the first core layer 81, the first memory layer 81, the fourth memory layer 86, the second core layer 83, and the second memory layer 84 are stacked in sequence. More specifically, the first die-to-die area 812 and the second die-to-die area 832 are vertically stacked, such that a die-to-die interface of the first core layer 81 is electrically connected to a die-to-die interface of the second core layer 83 directly through the transceiver TSV without using the interposer layer 201 as shown in FIG. 2 for transfer.

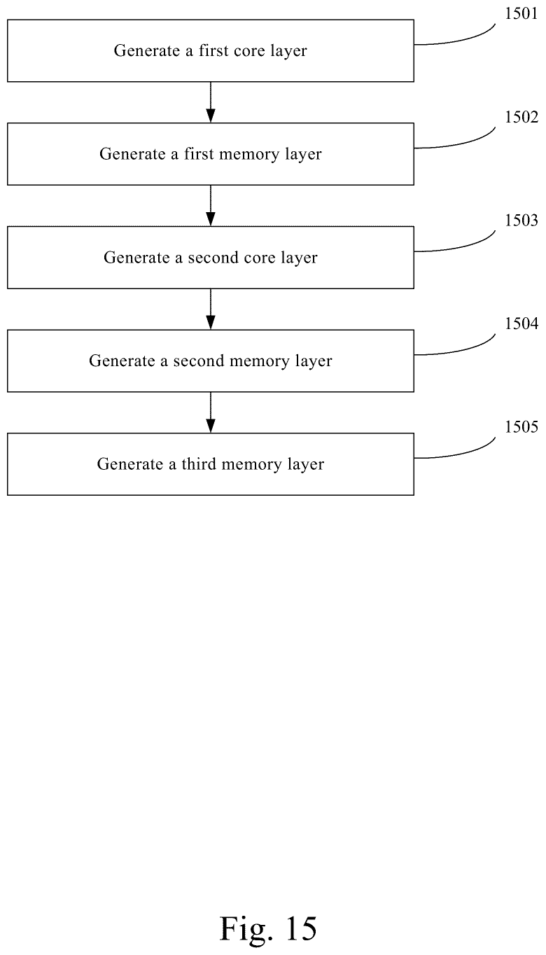

Another embodiment of the present disclosure provides a method for manufacturing a multi-core chip as shown in FIG. 9, and a flow chart thereof is shown in FIG. 15.

In step 1501, a first core layer 91 is generated, including a first operation area 911 and a first die-to-die area 912. The first operation area 911 is generated with the first operation circuit; and the first die-to-die area 912 is generated with a first transceiver circuit. In this step, a transceiver TSV is generated in the first core layer 91 to electrically connect the first transceiver circuit and a second transceiver circuit.

In step 1502, a first memory layer 92 is generated, including a first memory area 921 generated with a storage unit for temporarily storing operation results of the first operation circuit. In this step, a transceiver TSV is generated in the first memory layer 92 to electrically connect the first transceiver circuit and the second transceiver circuit.

In step 1503, a second core layer 93 is generated, including a second operation area 931 and a second die-to-die area 932. The second operation area 931 is generated with a second operation circuit; and a second die-to-die area 932 is generated with the second transceiver circuit.

In step 1504, a second memory layer 94 is generated, including a second memory area 941 generated with a storage unit for temporarily storing operation results of the second operation circuit.

In step 1505, a third memory layer 95 is generated, including a third memory area 951 generated with a storage unit for temporarily storing operation results of the first operation circuit or the second operation circuit. The third memory layer 95 is located under the second memory layer 94.

In this embodiment, the first core layer 91, the first memory layer 92, the second core layer 93, the second memory layer 94, and the third memory layer 95 are stacked in sequence. More specifically, the first die-to-die area 912 and the second die-to-die area 932 are vertically stacked, such that a die-to-die interface of the first core layer 91 is electrically connected to a die-to-die interface of the second core layer 93 directly through the transceiver TSV without using the interposer layer 201 as shown in FIG. 2 for transfer.

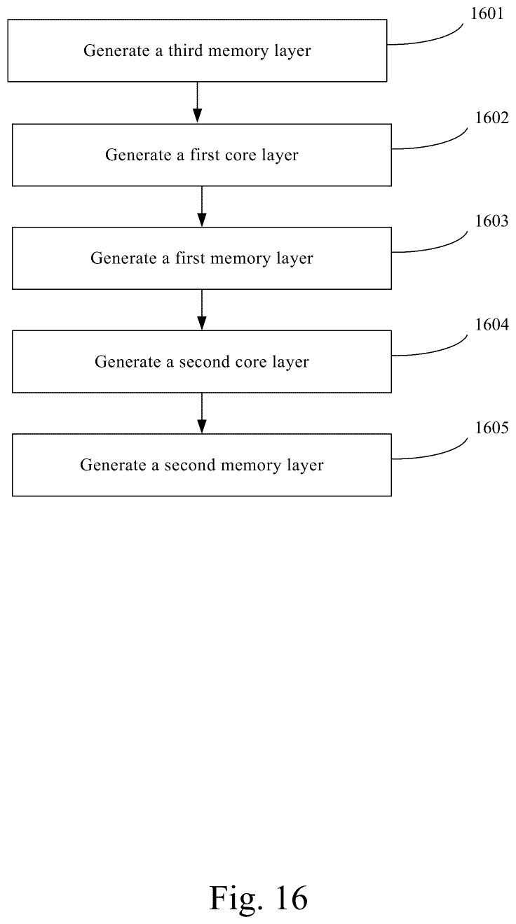

Another embodiment of the present disclosure provides a method for manufacturing a multi-core chip as shown in FIG. 10, and a flow chart thereof is shown in FIG. 16.

In step 1601, a third memory layer B is generated, including a third memory area 1021 generated with a storage unit for temporarily storing operation results of a first operation circuit.

In step 1602, a first core layer A is generated, including a first operation area 1011 and a first die-to-die area 1012. The first operation area 1011 is generated with a first operation circuit; and a first die-to-die area 1012 is generated with a first transceiver circuit. In this step, a transceiver TSV is generated in the first core layer A to electrically connect the first transceiver circuit and a second transceiver circuit.

In step 1603, a first memory layer D is generated, including a first memory area 1041 generated with a storage unit for temporarily storing operation results of the first operation circuit. In this step, a transceiver TSV is generated in the first memory layer D to electrically connect the first transceiver circuit and the second transceiver circuit.

In step 1604, a second core layer C is generated, including a second operation area 1031 and a second die-to-die area 1032. The second operation area 1031 is generated with a second operation circuit; and a second die-to-die area 1032 is generated with the second transceiver circuit.

In step 1605, a second memory layer E is generated, including a second memory area 1051 generated with a storage unit for temporarily storing operation results of the first operation circuit or the second operation circuit.

In this embodiment, the third memory layer B, the first core layer A, the first memory layer D, the second core layer C, and the second memory layer E are stacked in sequence. More specifically, the first die-to-die area 1012 and the second die-to-die area 1032 are vertically stacked, such that a die-to-die interface of the first core layer A is electrically connected to a die-to-die interface of the second core layer C directly through the transceiver TSV without using the interposer layer 201 as shown in FIG. 2 for transfer.

The solution of the present disclosure is to stack the core layers vertically so that the die-to-die area of the core layers are also stacked vertically. The two die to-die interfaces transfer data via the TSVs without using the interposer layer, such that the transfer path of the two die to die interfaces is greatly shortened, helping to improve the transfer efficiency between cores.

According to different application scenarios, the electronic device or apparatus of the present disclosure may include a server, a cloud-based server, a server cluster, a data processing device, a robot, a computer, a printer, a scanner, a tablet, a smart terminal, a PC device, an Internet of Things (IoT) terminal, a mobile phone, a traffic recorder, a navigator, a sensor, a webcam, a camera, a video camera, a projector, a watch, a headphone, a mobile storage, a wearable device, a visual terminal, an automatic driving terminal, a vehicle, a household appliance, and/or a medical device. The vehicle may include an airplane, a ship, and/or a car; the household electrical appliance may include a television, an air conditioner, a microwave oven, a refrigerator, an electric rice cooker, a humidifier, a washing machine, an electric lamp, a gas cooker, and a range hood; and the medical equipment may include a nuclear magnetic resonance spectrometer, a B-ultrasonic scanner, and/or an electrocardiograph. The electronic device or device of the present disclosure can also be applied to the Internet, Internet of Things, data centers, energy, transportation, public management, manufacturing, education, power grids, telecommunications, finance, retail, construction sites, medical care and other fields. Furthermore, the electronic device or apparatus of the present disclosure can also be used in application scenarios related to artificial intelligence, big data and/or cloud computing, such as the cloud, edge, and terminals. In one or more embodiments, electronic devices or apparatuses with high computing power according to the solutions of the present disclosure can be applied to cloud devices (such as cloud servers), while electronic devices or apparatuses with low power consumption can be applied to terminal devices and/or edge devices (such as smartphones or cameras). In one or more embodiments, the hardware information of the cloud device and the hardware information of the terminal device and/or the edge device are compatible with each other, so that according to the hardware information of the terminal device and/or the edge device, appropriate hardware resources can be matched from the hardware resources of the cloud device to simulate the hardware resources of the terminal device and/or the edge device, so as to complete the unified management, scheduling and collaborative work of end-cloud or cloud-edge-end.

It should be noted that, for the purpose of simplicity, some methods and their embodiments in the present disclosure are described as a series of actions and combinations thereof, but those skilled in the art may understand that the scheme of the present invention is not limited by the order of the described actions. Therefore, based on the disclosure or teaching of the present disclosure, those skilled in the art may understand that some of the steps may be executed in other orders or simultaneously. Furthermore, those skilled in the art may understand that the embodiments described in the present disclosure may be regarded as optional embodiments, which means the actions or modules involved therein are not necessarily necessary for the implementation of one or some solutions of the present invention. In addition, according to different schemes, the description of some embodiments of the present disclosure also has different emphases. In view of this, those skilled in the art may understand parts that are not described in detail in a certain embodiment of the present disclosure, and may also refer to relevant descriptions of other embodiments.

In terms of specific implementation, based on the disclosure and teaching of the present disclosure, those skilled in the art may understand that several embodiments disclosed in the present disclosure may also be implemented in other ways not disclosed herein. For example, with respect to the various units in the embodiments of the electronic device or apparatus described above, this disclosure splits them based on consideration of logical functions, but there may be other ways of splitting them in actual implementation. For another example, multiple units or components may be combined or integrated into another system, or some features or functions in a unit or component may be selectively disabled. As for the connection relationship between different units or components, the connection discussed above according to the drawings can be a direct or indirect coupling between units or components. In some scenarios, the aforementioned direct or indirect coupling involves a communication connection using an interface, where the communication interface may support electrical, optical, acoustic, magnetic or other forms of signal transfer.

In the present disclosure, a unit described as a separate component may or may not be physically separated, and a component shown as a unit may or may not be a physical unit. The aforementioned components or units may be located at the same location or distributed across multiple network units. In addition, according to certain needs, some or all of the units can be selected for realizing the purposes of the solutions described in the embodiments of the present disclosure. In addition, in some scenarios, multiple units in the embodiments of the present disclosure may be integrated into one unit or each unit may exist physically separately.

In some other implementation scenarios, the above-mentioned integrated unit may also be implemented in the form of hardware, that is, as a specific hardware circuit, which may include a digital circuit and/or an analog circuit, etc. Physical implementation of the hardware structure of the circuit may include but is not limited to a physical device, and the physical device may include but is not limited to a transistor, a memristor, or the like. In view of this, the various devices described in this disclosure (such as a computing device or other processing devices) can be implemented by appropriate hardware processors, such as central processing units, GPUs, FPGAs, DSPs, and ASICs. Furthermore, the aforementioned storage unit or storage device may be any suitable storage medium (including magnetic storage medium, magneto-optical storage medium, or the like), such as an RRAM (Resistive Random Access Memory), a DRAM (Dynamic Random Access Memory), an SRAM (Static Random-Access Memory), an EDRAM (Enhanced Dynamic Random Access Memory), an HBM (HighBandwidth Memory), an HMC (Hybrid Memory Cube), an ROM (Read Only Memory), an RAM (Random Access Memory), and the like.

The foregoing can be better understood according to the following articles:

Article A1. A multi-core chip, comprising: a first core layer, which includes a first operation area in which a first operation circuit is generated, and a first die-to-die area in which a first transceiver circuit is generated; and a second core layer, which includes a second operation area in which a second operation circuit is generated, and a second die-to-die area in which a second transceiver circuit is generated, wherein the first core layer and the second core layer are vertically stacked, and the first operation circuit and the second operation circuit transfer data between layers through the first transceiver circuit and the second transceiver circuit.

Article A2. The multi-core chip according to Article A1, connected to an off-chip memory and comprising a memory layer, wherein the memory layer includes: a memory area generated with a storage unit for temporarily storing operation results of the first operation circuit and the second operation circuit; an input/output area generated with an input/output circuit to serve as an interface for the multi-core chip to communicate with the outside; and a physical area generated with a physical access circuit to access the off-chip memory.

Article A3. The multi-core chip according to Article A2, wherein the memory layer is located between the first core layer and the second core layer and the memory layer is generated with a through silicon via (TSV) for electrically connecting the first transceiver circuit and the second transceiver circuit.

Article A4. The multi-core chip according to Article A2, wherein the memory area is located between the first core layer and the second core layer, and the second core layer is generated with a TSV for electrically transferring data of the input/output circuit.

Article A5. The multi-core chip according to Article A2, wherein the memory area is located between the first core layer and the second core layer, and the second core layer is generated with a TSV for electrically transferring data of the physical access circuit.

Article A6. The multi-core chip according to Article A1, further comprising: a first memory layer including a first memory area generated with a storage unit for temporarily storing operation results of the first operation circuit; and a second memory layer including a second memory area generated with a storage unit for temporarily storing operation results of the second operation circuit, wherein the first core layer, the first memory layer, the second core layer and the second core layer are stacked in sequence, and the first memory layer is generated with a transceiver TSV for electrically connecting the first transceiver circuit and the second transceiver circuit.

Article A7. The multi-core chip according to Article A6, wherein the first memory layer also includes a first input/output area generated with a first input/output circuit to serve as an interface for the multi-core chip to communicate with the outside, and the second core layer and the second memory layer are generated with input/output TSVs for electrically transferring data of the first input/output circuit.

Article A8. The multi-core chip according to Article A6, wherein the second memory layer also includes a second input/output area generated with a second input/output circuit electrically connected with outside of the multi-core chip through an input/output TSV.

Article A9. The multi-core chip according to Article A6, connected to an off-chip memory, wherein the first memory layer also includes a first physical area generated with a physical access circuit, and the second core layer and the second memory layer are generated with a physical TSV for electrically transferring operation results of the first operation circuit to the off-chip memory.

Article A10. The multi-core chip according to Article A6, connected to an off-chip memory, wherein the second memory layer also includes a second physical area generated with a second physical access circuit for transferring the operation results of the second operation circuit to the off-chip memory through a physical TSV.

Article A11. The multi-core chip according to Article A6, wherein the first core layer and the first memory layer are manufactured by face-to-face bonding, the first memory layer and the second core layer are manufactured by back-to-back bonding, and the second core layer and the second memory layer are manufactured by face-to-face bonding,

Article A12. The multi-core chip according to Article A6, further comprising a third memory layer, which includes a third memory area generated with a storage unit for temporarily storing the operation results of the first operation circuit, wherein the third memory layer is located above the first core layer.

Article A13. The multi-core chip according to Article A12, wherein the third core layer and the first core layer are manufactured by face-to-face or face-to-back bonding.

Article A14. The multi-core chip according to Article A1, further comprising: a fourth memory layer which includes a fourth memory area generated with a storage unit for temporarily storing operation results of the second operation circuit, wherein the fourth memory layer is located between the first memory layer and the second core layer, and the fourth memory layer is generated with a transceiver TSV for electrically connecting the first transceiver circuit and the second transceiver circuit.

Article A15. The multi-core chip according to Article A14, wherein the first memory layer also includes a first input/output area generated with a first input/output circuit to serve as an interface for the multi-core chip to communicate with the outside, and the fourth memory layer, the second core layer and the second memory layer are generated with an input/output TSV for electrically transferring data of the first input/output circuit.

Article A16. The multi-core chip according to Article A14, connected to an off-chip memory, wherein the first memory layer also includes a first physical area generated with a physical access circuit, and the fourth memory layer, the second core layer and the second memory layer are generated with a physical TSV for electrically transferring operation results of the first operation circuit to the off-chip memory.

Article A17. The multi-core chip according to Article A14, wherein the first core layer and the first memory layer are manufactured by face-to-face bonding, the first memory layer and the fourth core layer are manufactured by back-to-back bonding, the fourth memory layer and the second core layer are manufactured by face-to-face bonding, and the second core layer and the second memory layer are manufactured by face-to-back bonding.

Article A18. The multi-core chip according to Article A6, further comprising a third memory layer, which includes a third memory area generated with a storage unit for temporarily storing the operation results of the first operation circuit or the second operation circuit, wherein the third memory layer is located under the second core layer.

Article A19. The multi-core chip according to Article A18, wherein the third memory layer also includes an input/output area generated with an input/output circuit to serve as an interface for the multi-core chip to communicate with the outside.

Article A20. The multi-core chip according to Article A18, connected to an off-chip memory, wherein the third memory layer also includes a physical area generated with a physical access circuit for transferring the operation results of the first operation circuit or the second operation circuit to the off-chip memory.

Article A21. The multi-core chip according to Article A18, wherein the first core layer and the first memory layer are manufactured by face-to-face bonding, the first memory layer and the second core layer are manufactured by back-to-back bonding, the second core layer and the second memory layer are manufactured by face-to-face bonding, and the second core layer and the third memory layer are manufactured by face-to-back bonding.

Article A22. The multi-core chip according to any one of Articles A1 to A21, wherein each layer is packaged by flip chip ball grid array.

Article A23. The multi-core chip according to any one of Articles A1 to A21, wherein each layer is packaged by CoWoS.

Article A24. An integrated circuit device, comprising the multi-core chip according to any one of Articles A1 to A21.

Article A25. A board card, comprising the integrated circuit device according to article A24.

Article A26. A method for manufacturing a multi-core chip, comprising: generating a first core layer, which includes a first operation area in which a first operation circuit is generated, and a first die-to-die area in which a first transceiver circuit is generated; and generating a second core layer, which includes a second operation area in which a second operation circuit is generated, and a second die-to-die area in which a second transceiver circuit is generated, wherein the first core layer and the second core layer are vertically stacked, and the first operation circuit and the second operation circuit transfer data between layers through the first transceiver circuit and the second transceiver circuit.

Article A27. The method according to Article A26, wherein the multi-core chip is connected to an off-chip memory, and the method further comprises generating a memory layer between the first core layer and the second core layer, wherein the memory layer includes: a memory area generated with a storage unit for temporarily storing operation results of a first operation circuit and a second operation circuit; an input/output area generated with an input/output circuit to serve as an interface for the multi-core chip to communicate with the outside; and a physical area generated with a physical access circuit to access the off-chip memory.

Article A28. The method according to Article A27, wherein steps of generating the memory layer includes generating a TSV in the memory layer for electrically connecting the first transceiver circuit and the second transceiver circuit.

Article A29. The method according to Article A26, further comprising: generating a first memory layer which includes a first memory area generated with a storage unit for temporarily storing operation results of the first operation circuit; and generating a second memory layer which includes a second memory area generated with a storage unit for temporarily storing operation results of the second operation circuit, wherein the first core layer, the first memory layer, the second core layer and the second core layer are stacked in sequence, and steps of generating the first memory layer includes generating a transceiver TSV in the first memory layer for electrically connecting the first transceiver circuit and the second transceiver circuit.

Article A30. The method according to Article A29, further comprising generating a third memory layer, which includes a third memory area generated with a storage unit for temporarily storing operation results of the first operation circuit, wherein the third memory layer is located above the first core layer.

Article A31. The method according to Article A30, further comprising generating a fourth memory layer which includes a fourth memory area generated with a storage unit for temporarily storing the operation results of the second operation circuit, wherein the fourth memory layer is located between the first memory layer and the second core layer, and steps of generating the fourth memory layer includes generating a transceiver TSV in the fourth memory layer for electrically connecting the first transceiver circuit and the second transceiver circuit.

Article A32. The method according to Article A29, further comprising generating a third memory layer, which includes a third memory area generated with a storage unit for temporarily storing operation results of the first operation circuit or the second operation circuit, wherein the third memory layer is located under the second core layer.

The embodiments of the present disclosure have been described in detail above. Specific embodiments have been used in the specification to explain the principles and implementation manners of the present disclosure. The descriptions of the above embodiments are only used to facilitate understanding of the methods and core ideas of the present disclosure. Persons of ordinary skill in the art may change the implementation and application scope according to the ideas of the present application. In summary, the content of this specification should not be construed as a limitation on the present disclosure.

What is claimed:

1. A multi-core chip, comprising:
a first core layer including:
a first operation area in which a first operation circuit is generated, and
a first die-to-die area in which a first transceiver circuit is generated; and
a second core layer including:
a second operation area in which a second operation circuit is generated, and
a second die-to-die area in which a second transceiver circuit is generated, wherein
the first core layer and the second core layer are vertically stacked, and the first operation circuit and the second operation circuit transfer data between layers through the first transceiver circuit and the second transceiver circuit.

2. The multi-core chip according to claim 1, connected to an off-chip memory and comprising a memory layer, wherein the memory layer includes:
a memory area generated with a storage unit for temporarily storing operation results of the first operation circuit and the second operation circuit;
an input/output area generated with an input/output circuit to serve as an interface for the multi-core chip to communicate with the outside; and
a physical area generated with a physical access circuit to access the off-chip memory.

3. The multi-core chip according to claim 2, wherein the memory layer is located between the first core layer and the second core layer, and the memory layer is generated with a through silicon via (TSV) for electrically connecting the first transceiver circuit and the second transceiver circuit.

4. The multi-core chip according to claim 2, wherein the memory area is located between the first core layer and the second core layer, and the second core layer is generated with a TSV for electrically transferring data of the input/output circuit or data of the physical access circuit.

5. (canceled)

6. The multi-core chip according to claim 1, further comprising:
a first memory layer including a first memory area generated with a storage unit for temporarily storing operation results of the first operation circuit; and
a second memory layer including a second memory area generated with a storage unit for temporarily storing operation results of the second operation circuit, wherein
the first core layer, the first memory layer, the second core layer and the second core layer are stacked in sequence, and the first memory layer is generated with a transceiver TSV for electrically connecting the first transceiver circuit and the second transceiver circuit.

7. The multi-core chip according to claim 6, wherein the first memory layer also includes a first input/output area generated with a first input/output circuit to serve as an interface for the multi-core chip to communicate with the outside, and the second core layer and the second memory layer are generated with input/output TSVs for electrically transferring data of the first input/output circuit, and wherein the second memory layer also includes a second input/output area generated with a second input/output circuit electrically connected with outside of the multi-core chip through an input/output TSV.

8. (canceled)

9. The multi-core chip according to claim 6, connected to an off-chip memory, wherein the first memory layer also includes a first physical area generated with a physical access circuit, and the second core layer and the second memory layer are generated with a physical TSV for electrically transferring operation results of the first operation circuit to the off-chip memory,
wherein the second memory layer also includes a second physical area generated with a second physical access circuit for transferring the operation results of the second operation circuit to the off-chip memory through a physical TSV, and
wherein the first core layer and the first memory layer are manufactured by face-to-face bonding, and
wherein the first memory layer and the second core layer are manufactured by back-to-back bonding, and the second core layer and the second memory layer are manufactured by face-to-face bonding.

10. (canceled)

11. (canceled)

12. (canceled)

13. The multi-core chip according to claim 6, further comprising
a third memory layer, which includes a third memory area generated with a storage unit for temporarily storing the operation results of the first operation circuit, wherein the third memory layer is located above the first core layer, wherein the third core layer and the first core layer are manufactured by face-to-face or face-to-back bonding,
a fourth memory area generated with a storage unit for temporarily storing the operation results of the second operation circuit, wherein the fourth memory layer is located between the first memory layer and the second core layer, and the fourth memory layer is generated with a transceiver TSV for electrically connecting the first transceiver circuit and the second transceiver circuit.

14. (canceled)

15. (canceled)

16. The multi-core chip according to claim 13, wherein the first memory layer also includes a first input/output area generated with a first input/output circuit to serve as an interface for the multi-core chip to communicate with the outside, and the fourth memory layer, the second core layer and the second memory layer are generated with an input/output TSV for electrically transferring data of the first input/output circuit,
wherein the first memory layer also includes a first physical area generated with a physical access circuit, and the fourth memory layer, the second core layer and the second memory layer are generated with a physical TSV for electrically transferring operation results of the first operation circuit to an off-chip memory, and
wherein the first core layer and the first memory layer are manufactured by face-to-face bonding, the first memory layer and the fourth core layer are manufactured by back-to-back bonding, the fourth memory layer and the second core layer are manufactured by face-to-face bonding, and the second core layer and the second memory layer are manufactured by face-to-back bonding.

17. (canceled)

18. (canceled)

19. The multi-core chip according to claim 6, further comprising a third memory layer, which includes a third memory area generated with a storage unit for temporarily storing the operation results of the first operation circuit or the second operation circuit, wherein the third memory layer is located under the second core layer, wherein the third memory layer also includes an input/output area generated with an input/output circuit to serve as an interface for the multi-core chip to communicate with the outside.

20. (canceled)

21. The multi-core chip according to claim 16, connected to an off-chip memory, wherein the third memory layer also includes a physical area generated with a physical access circuit for transferring the operation results of the first operation circuit or the second operation circuit to the off-chip memory, wherein the first core layer and the first memory layer are manufactured by face-to-face bonding, the first memory layer and the second core layer are manufactured by back-to-back bonding, the second core layer and the second memory layer are manufactured by face-to-face bonding, and the second core layer and the third memory layer are manufactured by face-to-back bonding.

22. (canceled)

23. The multi-core chip according to claim 1, wherein each layer is packaged by flip chip ball grid array or packaged by CoWoS.

24. (canceled)

25. (canceled)

26. A board card, comprising a multi-core chip, the multi-core chip comprising:
a first core layer including:
a first operation area in which a first operation circuit is generated, and
a first die-to-die area in which a first transceiver circuit is generated; and
a second core layer including:
a second operation area in which a second operation circuit is generated, and
a second die-to-die area in which a second transceiver circuit is generated, wherein
the first core layer and the second core layer are vertically stacked, and the first operation circuit and the second operation circuit transfer data between layers through the first transceiver circuit and the second transceiver circuit.

27. A method for manufacturing a multi-core chip, comprising:
generating a first core layer including
a first operation area in which a first operation circuit is generated, and
a first die-to-die are in which a first transceiver circuit is generated; and
generating a second core layer including
a second operation area in which a second operation circuit is generated, and
a second die-to-die area in which a second transceiver circuit is generated, wherein the first core layer and the second core layer are vertically stacked, and the first operation circuit and the second operation circuit transfer data between layers through the first transceiver circuit and the second transceiver circuit.

28. The method according to claim 26, wherein the multi-core chip is connected to an off-chip memory, and the method further comprises generating a memory layer between the first core layer and the second core layer, wherein the memory layer includes:
a memory area generated with a storage unit for temporarily storing operation results of the first operation circuit and the second operation circuit;
an input/output area generated with an input/output circuit to serve as an interface for the multi-core chip to communicate with the outside; and
a physical area generated with a physical access circuit to access the off-chip memory.

29. The method according to claim 27, wherein steps of generating the memory layer includes generating a TSV in the memory layer for electrically connecting the first transceiver circuit and the second transceiver circuit.

30. The method according to claim 26, further comprising:
generating a first memory layer including a first memory area generated with a storage unit for temporarily storing operation results of the first operation circuit; and
generating a second memory layer including a second memory area generated with a storage unit for temporarily storing operation results of the second operation circuit, wherein
the first core layer, the first memory layer, the second core layer and the second core layer are stacked in sequence, and
steps of generating the first memory layer includes generating a transceiver TSV in the first memory layer for electrically connecting the first transceiver circuit and the second transceiver circuit.

31. The method according to claim 29, further comprising generating a third memory layer including a third memory area generated with a storage unit for temporarily storing operation results of the first operation circuit, wherein the third memory layer is located above the first core layer, and generating a fourth memory layer including a fourth memory area generated with a storage unit for temporarily storing the operation results of the second operation circuit, wherein the fourth memory layer is located between the first memory layer and the second core layer, and steps of generating the fourth memory layer includes generating a transceiver TSV in the fourth memory layer for electrically connecting the first transceiver circuit and the second transceiver circuit.

32. (canceled)

33. The method according to claim 29, further comprising generating a third memory layer including a third memory area generated with a storage unit for temporarily storing operation results of the first operation circuit or the second operation circuit, wherein the third memory layer is located under the second core layer.
